(19) United States
(12) Patent Application Publication
(10) Pub. No.: US 2010/0011550 A1
(43) Pub. Date: Jan. 21, 2010

(54) Controlled corrosion processes utilizing one atmosphere glow discharge plasma (OAGDP) in the manufacture of lead acid batteries

(76) Inventor: Battle Glascock, Soddy Daisy, TN (US)

Correspondence Address: DOWELL & DOWELL P.C., 103 Oronoco St., Suite 220, Alexandria, VA, 22314, US

(21) Appl. No.: 12/385,321

(22) Filed: Apr. 3, 2009

Related U.S. Application Data
(60) Provisional application No. 61/064,927, filed on Apr. 3, 2008.

(51) Int. Cl. H01M 4/82; C23C 14/34; C23C 14/35

(52) U.S. Cl. 29/2; 204/192.1; 204/192.32; 204/192.15

(57) ABSTRACT

Controlled corrosion processes in the production of lead acid batteries, wherein the processes utilize one atmospheric glow discharge plasma (OAGDP) to generate etched and chemically altered grids to increase the development of electrically conductive lead dioxide. The process involves placing pasted or unpasted lead or lead alloy grids in a chamber having two plasma-generating electrodes therein. A feed stream is directed into the chamber and passes between the electrodes to develop a plasma at atmospheric pressure. In the plasma, the components of the feed stream break down into atomic and reactive species to create a reactive environment. When the lead or lead alloy grids are exposed the reactive environment, chemical reactions occur between the reactive species and the lead components in the grids to chemically etch and remove contaminates from the grids, as well as form a uniform crystalline structure of lead nitrate across the grid surface, which can react to form a layer of lead dioxide on the grid surface.

### CROSS-REFERENCE TO RELATED APPLICATION(S)

The following application is a non-provisional application claiming priority to U.S. provisional application No. 61/064,927, filed Apr. 3, 2008, and entitled “New Process for Controlled Corrosion Processes Utilizing One Atmosphere Glow Plasma (OAGDP) in the Production of Lead Acid Batteries,” the subject matter of which is incorporated by reference in its entirety herein.

### FIELD OF THE INVENTION

The present invention is directed to processes for improving the efficiency of lead acid batteries, as well as for optimizing the manufacturing process therefor. The method of the invention involves using one atmosphere glow discharge plasma (OAGDP) during the manufacture of lead acid batteries to control corrosion processes within the battery, as well as increase the wettability of treated surfaces within the batteries, by forming a lead nitrate layer on lead or lead oxide grids grids and allowing the nitrate to react with lead sulfate and water in a paste to form a coating of lead dioxide the grids.

### BACKGROUND

A battery is an energy storage device in which chemical energy is converted to electrical energy via an electrolysis process utilizing a redox reaction. A redox reaction is a chemical reaction in which one component is oxidized by losing electrons, and another component is reduced by gaining electrons. The oxidation reaction occurs at an anode, while the reduction reaction occurs at a cathode. Further, the combination of an anode and a cathode separated by separator is known as a cell.

The development of the battery is often credited to Alessandro Volta. In his “Voltaic Pile” experiment, Volta investigated the effects produced when different metals are wetted with salt solutions. He stacked copper and zinc plates alternately and placed a piece of cardboard soaked in salt solution between each plate. This assembly generated an electrical spark when the two dissimilar metallic plates were connected by an external conductor. Although not in a usable and practical form, it demonstrated the electro motive force of dissimilar metals and thus was the basis of the chemistry and future of batteries.

Gaston Plante discovered and developed the lead acid battery in the 1860's based on Volta's “Voltaic Pile.” Plante discovered that by using two lead plates in a solution of sulfuric acid and repeatedly charging and discharging the assembly, he could build up the power storing capability of the system by building thicker and thicker layers of lead dioxide on the surface of the positive plate. The build up of the “active material” on the surface of the positive plate was very time consuming and thus not a practical means of bringing the assembly to a useable form. This discovery demonstrated the rechargability of the lead acid battery as being its most advantageous trait.

Camille Alphonse Faure further refined Plante's basic lead acid battery by using a pasted plate for faster lead dioxide formation. Faure made the paste by generating lead oxide, PbO, and mixing it with water and sulfuric acid. He spread the paste mixture over the surface of a lead plate and allowed it to dry. Faure then carried out the Plante process of transforming the mixture to lead dioxide, PbO₂.

The chemistry involved in the Faure approach was based on the observation that when the Plante plates were discharged, the formed layers of lead dioxide were transformed to lead sulfate. Faure's idea was to apply a thick layer of the lead sulfate, which is easily formed into lead oxide by the addition of sulfuric acid, thus providing an artificial thick layer of a precursor material for the development of the desired lead dioxide when the assembly was charged or formed. Although a dramatic decrease in the time required for the formation of a thick layer of active material was seen, the problem of active material retention on the surface of the flat lead plate was a major problem that prevented practical use of Faure's system.

To address the problems of the Faure system, namely the issue of active material retention on the plate, Sellon, Volkmar, and Brush used a perforated plate to assist in the adhesion of paste onto the plate surface. The use of the perforated plate drastically decreased the time for formation of active material over the standard Plante flat pure lead plate. Faure's discovery, along with the perforated grid discovery, allowed mass production of lead acid batteries and their subsequent use in many different applications.

The modern lead acid battery is still manufactured with these basic ideas and is found in wide spread use in various applications for the chemical storage of electrical energy. Stand by power as well as direct supply of electrical power for a myriad of applications has lead to the present day 45 billion dollar world wide market.

As set forth above, the lead acid battery utilizes a repeated redox reaction involving oxidation of lead by sulfuric acid at an anode and the reduction of lead dioxide by sulfuric acid at a cathode. The fully charged battery design allows for the development of a lead plate or electrode by a special process and the development of another electrode consisting of primarily lead dioxide in a similar process with both submerged in an electrolyte of sulfuric acid. The lead dioxide on the positive plate is referred to as “positive active material (PAM),” and the pure lead on the negative plate is referred to as “negative active material (NAM).” The lead plate is mounted adjacent to a lead dioxide plate with both plates being completely separated by a porous dielectric material called a separator.

On discharge, the redox reaction is initiated. The lead electrode is oxidized and supplies positive ions to the electrolyte, which renders the plate negative in charge, and thus it is referred to as the negative post or negative terminal of the battery. The lead dioxide electrode is reduced and supplies electrons to the electrolyte, leaving the plate positive in charge and thus is referred to as the positive post or positive terminal.

LEAD ANODE: Pb(s)+SO₄²⁻(aq) [symbol] PbSO₄(s)+2e⁻∈⁰=0.356 V

LEAD DIOXIDE CATHODE: PbO₂(s)+SO₄²⁻(aq)+4H⁺+2e⁻ [symbol] PbSO₄(s)+2H₂O(l)∈^{o}=1.685 V

When an external conductor is placed between the positive and negative poles of the battery, an electrical bridge is established, which allows the chemical reactions to take place. Several chemical reactions are initiated within the cell, thus transferring electrons from the negative pole through the external conductor to the positive pole. This allows the reaction at the negative pole to feed the reaction taking place on the positive pole. As the redox reaction proceeds when the battery is discharged, the lead and lead dioxide active materials on the negative and positive plates, respectively, are both transformed into lead sulfate, PBSO₄, with the electrolyte being converted to water. If any one component proceeds through its reaction and is fully transformed to a depleted state, the battery no longer provides an electrical potential.

A primary advantage of the lead acid battery is its inherent ability to be recharged by the application of a reverse potential on the terminals. During recharging, the lead sulfate on the negative plate is converted back to lead, and the lead sulfate on the positive plate is converted back to lead dioxide. In addition, the water is converted back to sulfuric acid.

As can be seen by the chemical equations above, the electrical potential between lead and sulfuric acid generates a total electrical potential of −0.356 volts, and the electrical potential between lead dioxide and sulfuric acid develops a +1.685 volt potential. This assembly therefore develops a total overall potential between the positive and negative posts of a cell of approximately 2 volts. In other words, this two volt assembly is referred to as a “cell.” There can be any number of positive and negative plate combinations, and the like plates are joined together to form just one negative pole and just one positive pole.

Several cells can be joined together in series or in parallel, with the most common practice being the joining of cells in series. This allows for the additive voltage of each cell, and thus batteries of 2, 4, 6, 8, 10, 12 volts etc, are possible, depending on the final desired application. The thickness of the plates, surface area of each plate, the amount of active material on each plate, and the number of plates are variables that a manufacturer can change to design the perfect battery for the end use.

The active material on the positive and negative plates is a very brittle material and therefore must be supported by a skeletal frame that can withstand the corrosive atmosphere inside the battery. The skeletal frame, which is credited to Sellon, is typically a grid made of lead or lead alloy. The grid supports the active material by having openings or pores located across its entire surface. The active material is not applied directed to the grid pores in a final state but is “formed” by a special manufacturing process developed by Faure.

In addition to being the support system for the active material, the lead or lead alloy grid is the current carrying frame work inside the battery assembly. The lead acid battery grid is made of pure lead or lead alloy consisting of a base metal of lead and various percentages of alloying elements, such as antimony, tin, silver, calcium, etc., which are used to enhance the mechanical, electrical and corrosive resistive characteristics of the grid for its intended service.

There are various methods of manufacture for battery grids, with the positive and negative grids having different dimensional thicknesses and pore opening sizes depending upon the manufacturers design. Methods of manufacture of the grid include book mold casting, strip casting with subsequent expanded metal or punching operations, all designed to deliver a skeletal grid with open pores for the future application of the lead oxide/lead sulfate paste material.

The open areas of the grid provide support for the paste or active material during production, as well as a retention means for the active material during the battery use. The grid webbing, with the associated support of active material therein, establishes an array chemical reaction sites across the entire surface of the grid. The grid acts as the current collector and distributor in both discharge and charge modes. The grid is subjected to a very harsh duty with the requirement of active material structural support to withstand continual expansion and contraction of the active material during cyclical charge and discharge operations, as well as resistance to vibration of the battery in is final service, all while submerged in a corrosive environment.

To form the active material paste for application to the grid, small lead particles, which are generated by atomization processes or through grinding operations, are subjected to an atmosphere containing oxygen and moisture, thus allowing the natural corrosion of the lead to the more stable lead oxide molecule with a percentage of free lead or unoxidized lead. Lead oxide with the percentage of free lead is the precursor material for the manufacture of the active material, lead and lead dioxide.

Lead oxide is typically generated by milling two processes, namely ball mill or Barton pot systems. Ball mill or Barton pot systems perform essentially the same overall process, but each has significantly different modes of operation with resultant differences in the oxide thus produced. The resultant material of each process is essentially a powdered form of lead oxide with a small percentage, 20% typically, of raw or free lead metal. Precise control of the operation specifications will determine the particle size, acid adsorption, and free lead content, as well as other critical process dependant variables that are closely monitored during production.

The Ball mill is considered a low temperature process due to the fact that this process relies on mechanical fracturing and pulverizing processes of precisely sized lead pellets in a tumbling drum to generate very fine particles of pure feed metal. The fractured particles of lead are brought into contact with water and oxygen in a steady flow of air where it is oxidized and subjected to further milling. When the particles are small enough, they will be entrained into the system air stream where they are carried to a dust collection system and further to a silo for storage.

The Barton pot method is considered a medium temperature process where molten lead is dosed into a vessel in a steady liquid stream where a spinning paddle makes contact with the molten lead stream. This action disperses the molten lead in a spray within the inner chamber of the pot. The lead solidifies in the air and is subjected to a fresh air stream similar to the ball mill thus allowing oxidation of the raw lead to take place. As the lead particles are oxidized in the reactor pot, they are mechanically milled by the mixer blades and thus reduced in size to enable their capture by the process air stream for capture in a dust collection system similar to the ball mill process.

In both systems, air is pulled through the relative chambers, and lead dust is continuously pulverized into smaller particles until it is light enough to be carried out of the chamber in the feed air stream to be collected in a dust collection system. The powder is then stored for future use in mixing operations.

To form a paste, the lead oxide powder formed in the milling operation is delivered to a specialized paste mixing system where it mixed with fixed quantities of water and sulfuric acid to a certain consistency with certain compounds added to the mix, depending on the use of the paste for a positive grid or a negative grid. When forming a paste for a negative grid, the additive typically includes a flocks material to affect the formed porosity of the negative active material.

The addition of sulfuric acid allows for the development of lead sulfate within the paste matrix. The lead sulfate, when mixed, cured, and formed into active material during a formation process, establishes a crystalline structure that will form the additive mass crystalline structure of a final lead acid battery assembly. The development of specific lead sulfate crystals in the mixing and propagation in curing operations is critical to the establishment of properly formed lead dioxide for a particular battery application.

The lead sulfates that are chemically formed during the paste-making operation, depending on the conditions and additives used therein, are better defined as being precursor salts of lead sulfate with tribasic structure of 3 PbOPbSO₄H₂O or 3BS, which is a small needle-like form with a large overall surface area. The 3BS form is a desirable precursor material for the development of alpha lead dioxide used in short burst high amperage applications, such as SLI or AGM batteries used in cranking of internal combustion engines, for example. These batteries typically act as standby power reservoirs and are only called upon for short bursts of energy.

Other applications that require the deep discharge of the cell would require a tetra basic lead sulfate precursor material with its large crystalline structure and low surface area. This is a very strong crystalline form that provides the precursor material for the development of beta lead dioxide in the active material after formation. This form provides strength and durability for deep discharge or long service life systems such as fork truck or telecommunications applications. The tetra basic lead sulfate crystal has the form of 4PbOPbSO₄ and is commonly referred to as 4BS.

These particular forms of the lead sulfate salt in the paste is initiated in the selection of the oxide milling process, ball mill or Barton pot, and established by the mixing recipe and temperature and time. They are also propagated in the curing process discussed below where the curing temperature and humidity cycle controls the crystalline type, size and overall quantity in the final active mass.

After the paste is formed in the paste mixing system, the lead or lead alloy grids are presented to a pasting machine either in a continuous strip or in individual panels, two grids attached together, or as individual plates, which presses lead oxide/lead sulfate paste into the surface of the grid. The pasting operation is critical in that the means by which the paste is applied to the surface of the grid has a very large impact on the overall integrity of the paste to grid contact integrity, initially as mechanical adhesion forces are concerned and as a determinate of the overall integrity of the electrical continuity of the final formed plate. Several very specialized pasting systems have been developed to provide uniform coverage of the paste on both the top and the bottom of the grid surface at the inner webbing or rib wall. In such systems, the paste is typically applied on the top surface of the grid under pressure so that the paste moves downwardly from the top surface toward the bottom surface. While these systems allow for proper coverage of the topside of the grid, they provide less than uniform coverage on the bottom side of the grid. Orifice pasters are an example of a fairly complex paster that is used to overcome this uneven paste coverage. This operation yields a neatly packaged grid/paste combination ready for curing and eventual assembly and formation.

A surface drying operation, referred to as a flash dryer, is located at the discharge of the pasting operation and subjects the pasted plates to a short dwell of high temperature air on the tops and bottom of the grid as each grid is carried through an oven while lying on a flat belt conveyor. The system is designed to provide a surface drying effect of the freshly pasted grids that enables the stacking of the plates for processing in the curing operation to prevent plate sticking.

After pasting, the wet pasted plates are delivered to a controlled atmosphere chamber that promotes the growth of paste matrix crystals, as well as ensures that the paste is dried completely prior to cell assembly. Once the grids are joined with the paste and the paste is cured and dried to an almost concrete like consistency, the paste is rigidly held in the grid pores by mechanical forces and to some extent, by corrosion caused by chemical reactions between the paste and the grid at interspersed sites at the grid surface. The chemical bridges are not uniform and thus do not ensure electrical continuity between the hard paste and the grid wall. Many additives and processing techniques have been utilized to promote the establishment of uniform contact between the paste and grid, but due to the location of naturally occurring lead oxide on the surface of the grid, as well as contaminates that are found on the grid surface from previous manufacturing operations, uniform continuity is all but impossible.

As stated previously, the curing operations are a primary means by which the propagation of the desired crystalline structure in the active material matrix is established and maintained. Precise control of the curing temperature and humidity as well as the air flow within the chamber is critical to the composition of the final product.

The curing operation also provides the proper atmosphere for the conversion of the free leads in the paste material to lead oxide and lead sulfate as process continues. It has been thought that the conversion of free leads in the curing operation serves as a means to promote proper grid to paste adhesion, among other things, but recent studies have shown that this is not the as effective as desired. Conversion of free leads does, however, assist in the establishment of active material structural integrity, as well as promotes the development of desired chemical morphology.

Once the grids are completely dried in the curing operation, special tabs are placed on the top most section of each grid to enable the joining of common plates. After the tabs are secured to the grids, the grids are assembled into battery cells. Each battery cell comprises alternating positive and negative plates with a separator in between. The separator is designed to enable ionic flow through the electrolyte and in between the plates but prevents physical contact between the positive and negative plates. If the plates contact each other during operation, the cell will short cycle electrically and render the batter useless.

Once assembled in alternating positive and negative plates with a separator in between, the common tabs of like potential plates are inserted into separated slots of a plastic battery case. The case is designed to allow for the total number of cells as described above that will provide the total voltage of the final assembly.

The assembled cells in the case are sent to the Cast on Strap operation or “COS.” The strap is a resultant connection of like plates by melting the tabs of like potential plates together to form a continuous connection between the negative plates and a continuous connection between the positive plates in a given cell. This operation is carried out without any short circuit between the negative bank of plates and the positive bank of plates.

Each cell is then connected to one another by a lead conductor that joins the opposing potential bank of plates in each cell to the opposite potential bank of plates in the adjacent cell. This operation carried out by a through the partition welder. The outermost cells will have a positive terminal on one outer side and a negative terminal on the opposite side of the case. This assembly allows for the additive cell voltages, as described previously. A plastic lid is placed over the assembly with the positive terminal and the negative terminal located on either end of the case being allowed to protrude through the top of the case lid. The cell assembly is sealed to the case by melting the plastic case and case lid at their contact points then pressing the two together. Sealing of the case must ensure that the electrolyte in each cell is not allowed to mix with the electrolyte in the adjacent cell. The strap is the current carrying pathway and the means by which the individual cells are joined in series and the battery terminal is mounted to allow connection to the external load.

The formation process is the key to the development of the final active material on the plates and renders the battery operable. This process is based on the original Plante method, as well as innovations developed by Sellon and others. It is the means by which the paste material is converted to active material on the lead or lead alloy grids.

In the formation process, the electrolyte of a specific gravity designed to promote proper formation of the active material is added to each cell. A special charging system is connected to the positive and negative terminals, and current is applied. The lead oxide/lead sulfate and negative expander paste on the negative grid is converted to pure sponge lead with the lead/lead sulfate paste on the positive grid being converted to pure lead dioxide. A fully charged battery consists of pure sponge lead negative plate and a positive plate of lead dioxide with separator in between, all submerged in an electrolyte of sulfuric acid.

Due entirely to the fact that the lead or lead alloy grids are made of a lead metal, the natural affinity of this material is to immediately form a corrosion layer of lead oxide over the entire surface of the grid when exposed to the atmosphere. The grids also have surface contaminates from their manufacturing process, such as oils and debris that collect across the surface, that increase surface resistance in the assembled system. Lead oxide is an electrically resistive material, and the location of this material at such a critical junction point in the battery assembly leads to detrimental operational characteristics of the system. Any resistive material or contaminate will inhibit the establishment of a continuous electrical, chemical, and mechanical bridge between the grid and active material.

Many different grid designs have been utilized to enhance active material adhesion and retention on the grid surface. Many different curing profiles, paste additives, and electrolyte formulas have been specified to promote the adhesion of the active material to the grid surface, all with the intent to increase electrical conductivity and mechanical and crystalline structural grip of the active material to the grid surface.

The adhesion of the freshly applied paste to the surface of the grid is based primarily on grid design and relies on mechanical gripping of the dried paste. It is only after formation that uniform chemical bridges are established. As can be seen by Faure's plate not standing up to the rigors of the battery cycling, and thus the shedding off of the pasted on active material, it is very obvious that the homogeneity of the grid to active material interface is very weak and, in fact, is discontinuous on a micro scale.

The paste material is composed of mainly lead oxide and lead sulfates, as well as pure lead. Lead oxide and lead sulfate have a substantially higher electrical resistivity compared to that of the lead or lead alloy grid and the formed active material. As such, the initial resistance to electrical flow during the initial stages of formation is very high across the grid to paste interface, as well as through the unformed paste.

The formation of a lead acid battery active material is primarily dependant on the ability of the positive plate assembly to convert the lead sulfate contained in the hard paste matrix to lead dioxide during formation. When a new battery is connected to the formation charging system, the applied current is designed to provide a certain amperage and voltage that initiates the development of active material at the interface of the grid to unformed lead oxide/lead sulfate material interface. The active material is lead dioxide on the positive plate and pure lead on the negative. It is at this junction point that the active material is established initially and builds outwardly as the formation process continues. The formation is complete when the entire mass of material on the positive and negative plates is converted to lead dioxide on the positive and sponge lead on the negative plates or converted to a point where further charging does not lead to an increase in energy output of the final product.

The initial charging current is subject to extremely high resistance due to the lead oxide surface layer, as well as surface contaminates being located in between the grid and paste interface. The current must overcome this resistance and does so at paths of least resistance wherever they may be across the entire surface of the interface region. This means that preferential active material nucleation sites are established where current is allowed to flow most readily, thus developing pockets of converted active material at the grid surface. These pockets or spot locations of newly converted active material decrease the resistance of the circuit at these locations, which are widely spaced, and only where the electrical bridge is allowed to be established. The formation of active material continues outwardly in radial directions through the matrix until a direct path of active material is built to the outer surface of the plate.

The prevention of uniform electrical conductivity across the entire grid to paste interface yields very high formation power requirements and extremely high formation temperatures. The lead sulfate and lead oxide in the paste are very poor conductors of electrical current and must rely on the surrounding current conducting material to be able to react with the electrolyte in order to be formed into active material. Lead sulfate and lead oxide materials located at the interface of the grid to paste regions that are not subject to proper electrical flow are under formed and underutilized as current conductors and active material contributors.

During battery cycling and due to poor conversion of the paste material to active material as caused by the limitations of available electrical conductivity at the grid to paste interface, the sulfate material is retained within the matrix pores and at the grid to active material interface. Electrolyte pathways become clogged, and thus the electrolyte is not allowed to circulate. With the establishment of poor current flow and the limitation of electrolyte flow, the conversion of lead sulfate to active material is greatly inhibited. This strengthens the preferential electrical pathways and limits the amount of active material available for usable work with in the matrix at an increasing rate. It also promotes the retention of lead sulfate in pocket areas of the active material mass that gradually hardens and become retained non-reactive regions. This is the beginning of battery sulfation, which eventually leads to battery failure.

Excessive shedding of active material from the plate surface is promoted by the lack of proper current conducting pathways from the grid to the outer surface of the active material, thus allowing lead sulfate to be unconverted to active material on recharge. Shedding of active material is not necessarily caused by the grid to active material interface, but due to the lack of electrical continuity between the grid and active material during subsequent charge and discharge cycles, unconverted lead sulfate regions build in size over time. This causes continual weakness within the active material matrix and a subsequent weakening of the retention strength of the active material on the grid surface.

Differences in thermal expansion coefficients between the active material and the grid, and the fact that the active material will expand and contract as the battery is charged and discharge as it is transformed from one material structure to another, lead to a cyclical rise and fall of mechanical stress energies at the points of contact at the grid to active material interface. This causes a continual breakdown of the electrical bridge in this region, which promotes shedding of active material and battery failure over time.

As a result, the overall inefficiency of the system is quite large. The total theoretical available power of the system is only partially utilized, 25% to 35%, and as such, much of the available active mass never provides useful work.

To enhance the contact between the grid and active material for increased formation efficiency, as well as increased battery life and operational efficiency, U.S. Pat. No. 6,803,151 describes a process for coating the unpasted positive and negative lead grid with a coating of lead dioxide. While the inclusion of a layer of electrically conductive lead dioxide may be beneficial to the manufacture and operation of the battery, the process disclosed in this patent requires the use of wet chemistry and cumbersome and expensive processes. The patent does detail the definite benefits of the final process, yet it is impractical in actual use.

Similarly, U.S. Pat. No. 4,046,642 discloses the use of nitric acid as a part of the electrolyte and as an additive to enhance the formation of active material at the interface regions of the assembly. The released nitrate portion of dissolved lead nitrate is released from the plates during formation and does not contribute to the chemistry of the assembly and in fact does not adversely affect the operation of the cell. This process requires a special formation process where the polarity of the plates being formed must be reversed in order to activate the benefits of the process. It also requires a change in standard operating procedures for the specific electrolyte chemistry and thus is cumbersome to utilize based on the varied sizes of batteries in production today. Another distinct disadvantage is the need for the precise control of the nitric acid levels in the electrolyte in order to prevent erratic and undesirable crystal growth and possible short circuits in the cell.

As an alternative to the wet chemistry and complicated processes associated with coating grids with lead dioxide and to the addition of nitric acid to the electrolyte, it is more advantageous to treat the metallic surfaces of the grids. One atmospheric glow discharge plasma (OAGDP) is a process comprised of a power supply designed to provide a specific voltage at a specific frequency between two insulated electrodes to allow the development of plasma at atmospheric pressures. The plasma is unique in that it is developed at atmospheric pressure with no special gasses required, as set fort in U.S. Pat. No. 5,387,842, among others.

As early as 1857, as reported by Werner von Siemens, spark discharge or corona discharge phenomena has been studied for various applications with varying degrees of success and application. It was not until modern technological advances in electrical insulating materials, as well as advances in electronic circuitry, that enabled a generation of a continual plasma field at atmospheric pressure. However, the use of plasma as a means of providing a specific atmosphere containing reactive species for the purpose of modifying or enhancing metallic surfaces has not yet been possible.

The basic OAGDP apparatus consists of two dielectric plates or electrodes that are precisely positioned opposite one another at a specific uniform distance. One plate is connected to the positive side of a special electrical circuit and the other is connected to ground. The electrical circuit delivers high voltage, high frequency power to the positive electrode, thus allowing for a sustained and uniform plasma field between the electrodes.

When a gas is delivered between the two electrodes, free electrons are captured by the charged dielectric electrodes. Through the high frequency change in polarity of the electrode charge, the electrons are forced to move at this same frequency in between the plate surfaces. This action results in an electron avalanche, thus generating the sustainable plasma field. When a feed gas is drawn in between the plates, the molecules in the gas are bombarded by the free electrons in the plasma field. This causes the molecular bonds in the molecules of the feed gas to be broken, consequently generating highly reactive species of the atomic components of the feed gas to be released into the gas stream.

The highly reactive metastable atomic species react very rapidly with each other, as well as surfaces of materials they are subjected to both inside the plasma field and on the discharge of the plasma field by the thus formed reactive gaseous species. By utilizing the generated reactive gases and controlling their chemical make up through the precise control of feed gases and materials prior to exposure in the plasma field, it is possible to design chemical formulae to deliver desired chemical reactions on exposed solid, liquid, and gaseous materials. These reactive discharge gases react with other molecular compounds causing breakdown of these materials or the development of new materials on a surface or in the resultant gas stream.

Once a molecule is separated into its component atoms, the individual atoms became very reactive with other atoms thus generated or with materials the reactive species are allowed to come in contact with. Once a molecule is separated into its component atomic particles in the OAGDP system, these particles rejoin in any number of different molecular configurations that can either generate stable molecular forms or unstable atoms and molecules, such as atomic oxygen or ozone, O₃, or other super oxidizers, such as O₄ and O₅, if oxygen is the only feed gas or N, NO, or other nitrogen containing molecules, if the feed gas is comprised of oxygen and nitrogen. The addition of H₂O in the form of atomized water entrained into the feed gas stream adds hydrogen to the reactive mixture thus forming hydrogen, oxygen, and nitrogen based materials. The addition of other gases such as CO₂ allows for the addition of carbon to the mix with subsequent development of hydrogen, oxygen, nitrogen and carbon based compounds.

It is when the generated gases are discharged from the plasma field that they are allowed to recombine with other atomic molecules generated in the plasma field to form other unstable or stable molecular bonds based on a hierarchy of reactions as determined by several factors. The recombination of the reactive species generated in the plasma field is time dependant with most of the highly reactive species participating in a chemical reaction within a very short period of time, microseconds, after leaving the plasma field. The gases can be used to perform certain tasks on materials which are brought into contact with the discharged gas stream. Depending on the time allowed after the gases leave the plasma field, specific reactants can be used to treat solid or liquid or even gaseous materials located outside the plasma field.

These reactive species will have an affinity to react with one another based on the concentrations of the individual species primarily, as well as the temperature of the atmosphere and the presence or absence of a catalyst. In general, there are four basic reactions that can occur in the reactive atmosphere created by OAGDP:

1) oxidation or the addition of an oxygen atom to another atom or molecule to form an oxide or increase an existing oxide to a higher level oxide form;

2) reduction or the removal of an oxygen atom to reduce the material to a lower form of the base oxide or form;

3) electron reduction; and

4) ionic decomposition.

The electron driven disassociation and ionization of the plasma constituents depend on the material being acted on and drive the formation of reactive free radicals and ionic species that are the primary mechanisms that attack the constituents of a gas, liquid, or solid material on a molecular level and cause the process to deliver a desired end result, such as surface etching of a material surface through oxidation.

The driving force for the reaction between the individual components of the gas stream follows a second order reaction model. Consequently, the speed or velocity of an individual reaction within the discharge gas stream and prior to contact with the treatment material will vary and is based on three basic factors:

1) the concentration of the various resultant atomic and molecular species, which changes over time as reaction rates progress;

2) temperature; and

3) the presence or absence of a catalyst.

The presence of a catalyst will lower the activation energy for a given reaction and thus enables a reaction to take place much more readily. The concentration component relies upon reaction rates between individual reactants that vary from the initial concentration to the final concentration of reactants based on time. Obviously, the time allowed for reactions to occur will have an effect on the exact concentration of available reactants. This means that the gaseous mass has an evolving reaction rate. Therefore, the concentration contribution to the overall reaction rate follows an evolving second order reaction scheme.

A second order reaction criteria is defined as V(speed of reaction)=k(CA @ a)(CB @ b) (CC @c) . . . (CN @ n). (CX @ x) is the concentration of component X, with x being the individual dependencies of V or time on the concentration of X. The sum of a+b+c . . . n is called the order of the reaction and is a concentration based component of the reaction rate, and k is the rate constant.

The rate constant k=A(frequency factor)(Boltzmann factor). The frequency factor is the fraction of molecules or atomic species that reaction criteria such as collision frequency and or molecular orientation. The Boltzmann factor is defined as ̂(−Ea/RT).

As indicated above, a majority of the reactive species generated in the plasma field are subjected to chemical reactions that take place almost immediately at the discharge of the field. It is the composition of the feed gas with the resultant discharge stream of reactive gasses that can be manipulated to produce a reaction on the surface of the treated material, the catalyst. It is this material that acts as a catalyst on which the reactive gases react upon thus driving the desired end result.

The precise control of the process variables, as well as the feed stock materials and their quantities, determine exactly what the desired reactants will be. Due to the high reactivity of the discharge gases, each atomic particle or reactive or non reactive molecule will constantly be acted upon by other surrounding species with a multitude of chemical reactions taking place. By selecting the desired resultant reactant and utilizing proper system controls for the feed stock material as well as temperature and humidity control of the reaction atmosphere, the resultant gas can now be formulated to cause a particular reaction, such as etching, molecular nucleation, or crystal growth on a material surface.

Thus, there is a need for a practical system for treating grids to enhance the electrical conductivity across the entire grid to paste interface to increase the formation of active material, enhance the contact between the grid and the active material, and improve the efficiency of the battery.

### SUMMARY

The present invention is directed to controlled corrosion processes in the production of lead acid batteries, wherein the processes utilize one atmospheric glow discharge plasma (OAGDP) to generate etched and chemically altered grids to increase the development of electrically conductive lead dioxide. The process involves placing pasted or unpasted lead or lead alloy grids in a chamber having two plasma-generating electrodes therein. A feed stream is directed into the chamber and passes between the electrodes to develop a plasma at atmospheric pressure. In the plasma, the components of the feed stream break down into atomic and reactive species to create a reactive environment. When the lead or lead alloy grids are exposed the reactive environment, chemical reactions occur between the reactive species and the lead components in the grids.

By adjusting the composition of the feed stream, as well as other process variables, such as relative humidity and temperature, the type of reaction between the grids and the atmosphere can determined and controlled. Preferably, the feed stream includes oxygen and nitrogen, which break down into various reactive species during the OAGDP system. These reactive species form nitric acid, without the need for complex equipment or external chemical other than air and water, which reacts with the lead in the grids to form lead nitrate. The lead nitrate reacts with water and sulfuric acid in the paste to form a lead dioxide coating on the grid.

As a result, there is no formation of high resistance lead oxide, and the formation of active material and contact between the grid and active material is greatly increased. Thus, the present invention makes it possible to reduce system inefficiencies, while increasing the system operational efficiency of the batteries and reducing warranty cost. The batteries manufactured pursuant to the controlled corrosion process deliver more power and present a significant increase in product utility. Further, the controlled corrosion processes increase the total power utility and decrease the cost of manufacturing through significantly shorter formation times and power consumption.

One of the primary benefits of the subject invention is to greatly affect the formation efficiency of the lead acid battery by enhancing and controlling the level of corrosion or promoting the corrosion of the outer surface of the base lead or lead alloy to develop a higher form of electrically conductive active material on both the positive and negative raw grids at the interface regions of the battery assembly. The disclosed invention also enables the establishment of very strong atomic bonds between the grid surface and active material, thus providing better adhesion of active material to the grid surface and increasing the electrical conductivity and electrolyte flow at the interface.

In addition, the present invention provides for elimination of contaminates and the naturally occurring lead oxide so that there is a dramatic increase in surface area of the grid. The establishment of a precursory layer of lead dioxide across the entire surface of the positive grid after pasting and formation and the establishment of pure lead at the negative grid to sponge lead interface promotes a higher integrity electrical bridge at all areas within the assembly. Consequently, the potential for the build-up of retained lead sulfate areas is reduced and a higher degree of electrical current and electrolyte flow to all areas of the active material as well as at the grid to active material interface is enabled.

Further to the benefits listed above, the treatment of the raw grid surface by the invention greatly affects the surface energy of the lead or lead alloy grid. By increasing the surface energy on the grid surface, the wet paste, when it comes into contact with the grid during pasting, has a higher degree of wettability. This dramatically increases the surface contact area and increases the structural support of the active material during the life of the battery. The wettability or surface energy of the lead or lead alloy grid is very low and as such, the wet paste does not readily flow across the grid surface and into surface pores when analyzed on a micro scale. By increasing the grip and promoting uniform electrical continuity of the paste to the grid, problematic paste adhesion issues currently seen while using a stamped grid or any other conventional grid type is greatly affected, and paste retention on the surface of the grid is much more efficient.

Another benefit of the disclosed invention is addressing the grid to active material interface and providing a substantial increase in material adhesion or the promotion of a homogeneous material bridge and the subsequent establishment of increased electrical continuity in this critical area of the system. This process enables the uniform establishment and growth molecular bonds between the grid and active material, thus dramatically increasing electrical conductivity and active material retention on the grid surface.

### BRIEF DESCRIPTION OF THE DRAWINGS

A better understanding of the invention will be had with reference to the attached drawings wherein:

FIG. 1. shows the ionization and activation of standard room air containing oxygen, nitrogen, and carbon dioxide in atmospheric plasma;

FIG. 2 shows electron and ion driven constituents driving oxidation and reduction reactions via electrophilic and nucleophilic attack against deoxyribonucleic acid;

FIG. 3. is an X-ray diffraction scan of a grid treated with the process of the present invention; and

FIG. 4 is a scanning electron micrograph of a grid treated with the process of the present invention.

### DETAILED DESCRIPTION OF THE DRAWINGS

The present invention involves controlled corrosion processes for the production of lead acid batteries utilizing one atmospheric glow discharge plasma (OAGDP) for the development of a reactive atmosphere to cause a desired chemical reaction on the surface of lead or lead alloy grids prior to pasting, as well as other like treated materials. The newly developed surface material thus formed is then subjected to standard manufacturing processes which cause the new surface treatment to chemically transform to other desired chemical forms which provide precursor material for the development of a uniformly distributed surface roughness, as well as a desired chemical surface material for the subsequent development of electrically conductive chemical bridges for the enhanced operation of the lead acid battery.

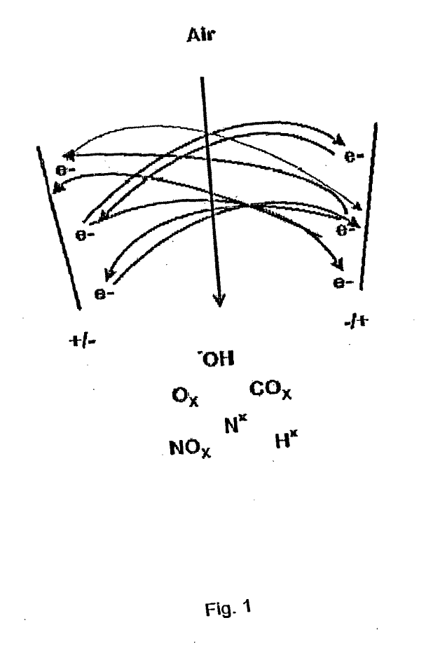

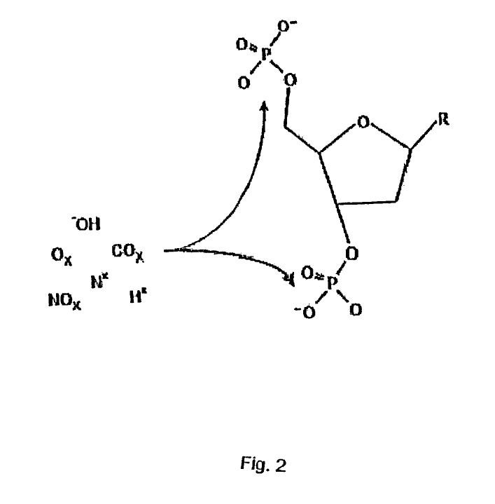

The OAGDP process creates highly reactive species of the molecules in a feed gas stream. For example, FIG. 1 shows the ionization and activation of standard room air in atmospheric plasma. By controlling the feed stock materials and utilizing specific system controls, including temperature and humidity of the reaction atmosphere, the resultant gas of OAGDP can be formulated to cause a particular reaction, such as oxidation, reduction, electron reduction, and ionic decomposition. FIG. 2 shows electron and ion driven constituents driving oxidation and reduction reactions involving deoxyribonucleic acid. Further, the time of exposure can be controlled to affect a linear crystalline growth rate on a grid surface.

The corrosion controlled processes utilize an OAGDP system with a specialized infeed gas and/or liquid which is atomized or evaporated prior to exposure of the resultant mixture to the OAGDP plasma field. Any given volume materials containing nitrogen, oxygen, and hydrogen in any number of different states of gas or liquid can be feed material to the OAGDP plasma field. Further, while the present invention is directed to the manufacture of lead acid batteries and components therefor, the corrosion controlled processes can be utilized in a multitude of different applications where chemical reactions are desired for the development of a specific end product.

With regard to the production of lead acid batteries, there are essentially two separate processes that occur in the treatment process of the present invention:

1) grid surface cleaning and etching of the naturally occurring lead oxide material and the removal of surface contaminates; and

2) formation of finely distributed lead nitrate crystals across the entire surface of the lead or lead alloy grid.

The surface thus developed is then used as a surface protector during storage of the grids. When the grids are pasted, the newly formed surface material reacts with the paste material components to chemically produce a new material and surface texture across the grid surface. This newly formed surface material further reacts during formation to produce a uniformly formed lead dioxide layer at the grid to lead dioxide active material interface on the positive plate and uniformly formed lead layer at the grid to sponge lead active material interface on the negative plate.

To begin the controlled corrosion process, lead or lead alloy grids or pasted grids are placed in a specialized chamber designed to allow for the placement of lead grids in a closed area, namely an inner chamber portion, that is isolated from the atmosphere in a main processing chamber portion and subjected to a negative pressure of approximately ½ WC. The chamber may be open or closed to atmosphere. The lead plates can be delivered in strip form or as individual plates, and the pasted plates can likewise be delivered in strip form or as individual plates.

A feed stream including nitrogen and oxygen is drawn into the chamber through a control valve. The feed stream can be air, a blended gas, water, hydrogen peroxide, or other liquid that provides precursor material for the generation of reactive species during the OAGDP process. The valve preferably allows for an air replacement rate of approximately 5% inside the chamber. The chamber has a recirculation fan positioned in such a way to continually recirculate the chamber air through a several plasma electrodes that are positioned perpendicular to the air flow.

The electrodes are designed to provide very low air resistance but can be made in any number of ways as long as the opposing electrodes are positioned at a finite distance apart to prevent field concentrations of current. One electrode is a high voltage electrode covered with a dielectric material, and the other electrode is a grounded electrode having a metallic conductor with no insulation. Alternatively, the grounded electrode is either open to the atmosphere in the chamber or is touching or imbedded into the surface of a conductive material, causing the conductive material to act as the grounded electrode. The conductive material can be a consumable or non-consumable material and can also be a liquid, semi-solid, or solid material. The electrodes can be flat plates, tubes, insulated copper wire, or any other insulated current conductor. The relative humidity is monitored and controlled by the atomization of water to allow for a particular relative humidity within the chamber at all times during the process.

As the air is circulated through the electrodes as they generate a plasma, the air is blown down the sides of the inner chamber and is released into the main processing chamber through side discharge slots that are positioned to allow air flow and distribution inside the chamber. The resultant activation of the atomic species in the feed gas stream breaks down the species into component atomic species within the plasma field. The discharge gaseous material will be comprised of various combinations of O, N, H, N₂, O₂, O₃, NO, N₂O₂, NO₂, H₂O₂, NH₃, HNO₃, and H₂O.

As the surface of the lead or lead alloy grid are subjected to the reactive off gases of the plasma field, the surface contaminates and the naturally occurring layer of lead oxide are chemically oxidized and etched and removed from the grid surface by the reactive gases through electron reduction and ionic decomposition. The exposure time is very short. It is the exposure of the raw base material, which in itself is very reactive, that allows the efficient reaction between the developed nitric acid (HNO₃) in the gas stream and the base lead takes place.

The nitric acid which is formed in the off gas stream, chemically reacts with the lead surface by the following reaction:

Reactive atomic nitrogen, N, and reactive atomic oxygen, O, are produced in the plasma atmosphere and combine to form nitrogen monoxide, NO.
Nitrogen monoxide, NO, reacts with atomic oxygen to produce nitrogen dioxide, NO₂, as follows:

2NO(g)+O₂==>2NO₂(g)

Nitrogen dioxide, NO₂, reacts with water and oxygen, O₂, to produce nitric acid (HNO₃), as follows:

4NO₂(g)+2H₂O(l)+O₂==>4HNO₃(l)

Nitric acid reacts with the lead surface to form lead nitrate (PbNO₃) by the following equation:

HNO₃+Pb=PbNO₃+H

As set forth above, the relative humidity is controlled by the atomization of water at the infeed gas stream. The discharge gas reactivity and chemistry are directly affected with the reaction rate of the nitric acid produced, thus being controlled precisely. Further, the atmosphere can be used in several ways but primarily is used to subject a material to the reactive gases delivered by the process to cause a chemical reaction on the surface of the treated material. Upon completion of the OAGDP treatment, the plasma source is turned off and the chamber air is evacuated to remove all process air and allow for fresh air to fill the chamber. Lastly, the treated grids are removed from the chamber.

The primary benefit of this reaction and process is that the newly developed lead nitrate surface on the lead grid provides a protective layer across the entire surface of the lead grid which is a very stable and prevents the establishment of lead oxide on the surface of the grid during long term storage. Further, as that lead reacts very readily with nitric acid to form lead nitrate, lead ions are provided by the grid surface thus etching the surface and allowing for a significant increase in surface area and roughness to promote the adhesion of applied lead oxide material in downstream operations. The uniformly formed lead nitrate crystals are later dissolved after the application of the paste thus yielding the evenly dispersed surface roughness in the form of sharp peaks and valleys on a micro scale which greatly enhances surface grip and area at the active material to grid interface.

### EXAMPLE

An example of the process utilizes a supply of atmospheric air or blended air comprised of primarily 79% nitrogen and 21% oxygen. The air feed stock is humidified with water to a relative humidity of at least 10% and as high as 100%, preferably approximately 70% relative humidity. The gas stream thus generated is then delivered to the plasma field. The resultant activation of the atomic species in the feed gas stream breaks down each species into its component atomic species within the plasma field. The discharge gaseous material will be comprised of various combinations of O, N, H, N₂, O₂, O₃, NO, N₂O₂, NO₂, H₂O₂, NH₃, HNO₃, and H₂O, as well as many other very reactive species of materials comprised of varying concentrations of the atomic feed stock.

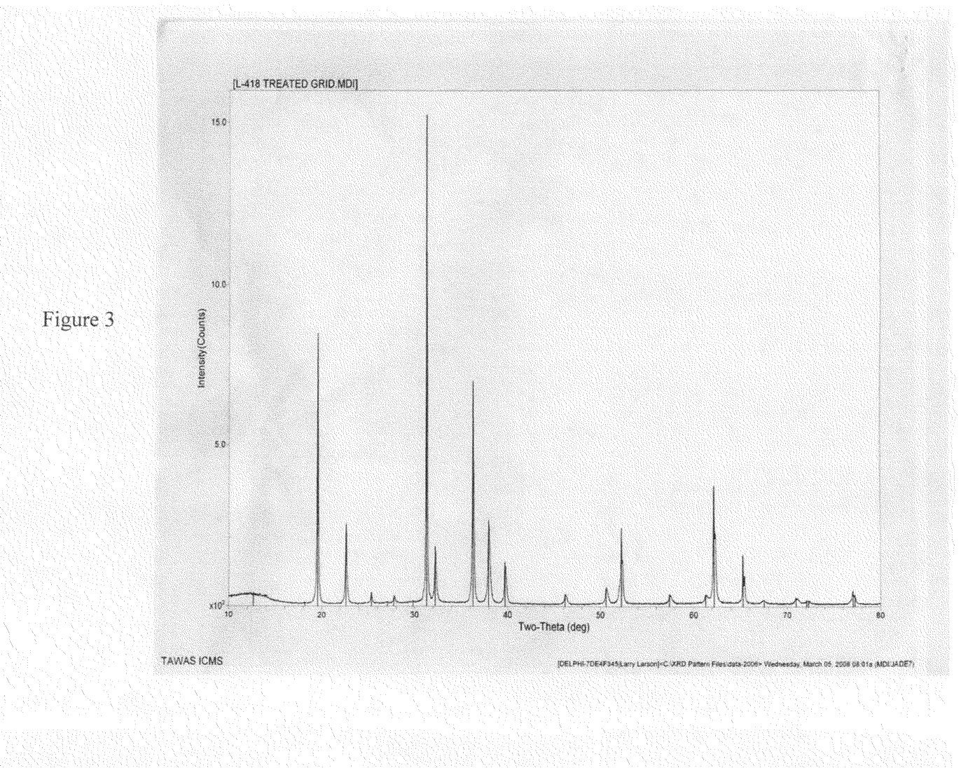

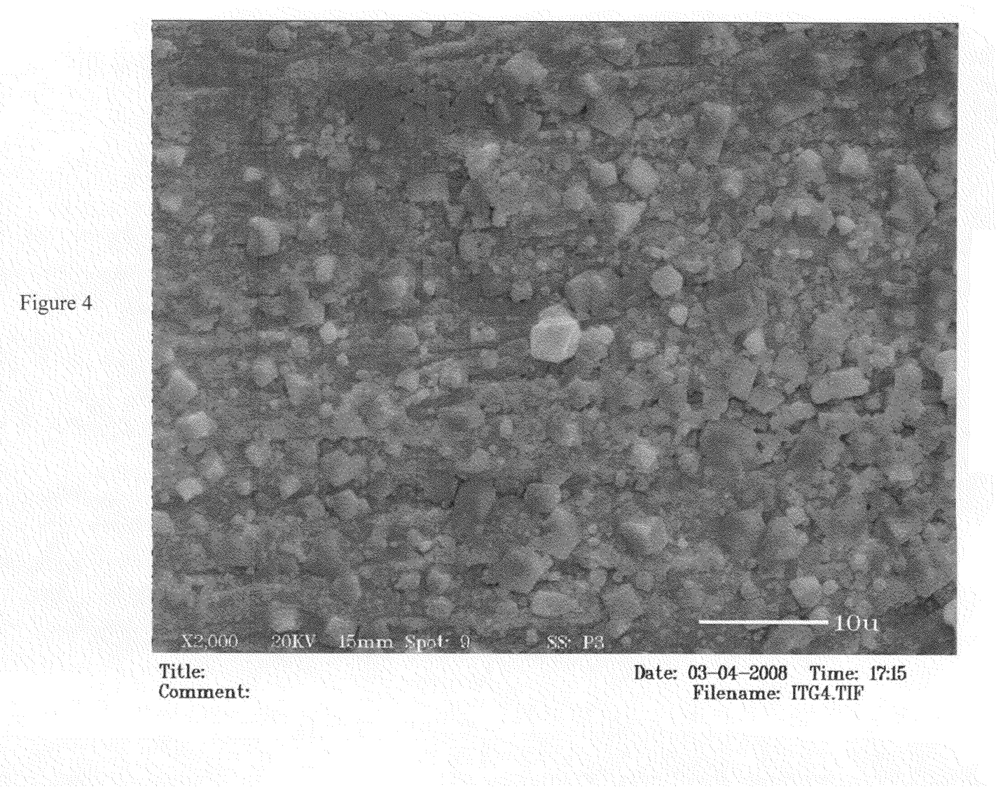

Since each one of these reactive materials has a propensity to form other reactive or non-reactive gases or if allowed, condensate or react on a catalyst surface, each material will etch and clean the contaminated and oxidized surface of the target grid and form liquid or solid materials comprising various concentrations of the atomic feed stock and components of the target material, such as nitric acid (HNO₃) reacting with the surface of lead to form lead nitrate. A grid treated with the process according to this example are shown in the X-ray diffraction image and the scanning electron micrograph of FIGS. 3 and 4, respectively. As shown in FIG. 3, the process created pure lead nitrate material on the grid. Further, FIG. 4 shows the formation of lead dioxide on the grid surface.

After the OAGDP treatment, the treated unpasted grids are pasted with a lead oxide and lead sulfate paste during a pasting process of conventional battery production. Lead nitrate Pb²⁺(NO₃)₂ is a neutral molecule and is one of the only lead based compounds that is readily soluble in water. The application of the water and sulfuric acid based lead oxide and lead sulfate with free lead paste to the surface of the grid during the pasting operation, promotes among others, two specific chemical reactions that are both beneficial to the development of a desired chemical and mechanical intermediate layer between the lead grid and the applied paste.

When the water component comes into contact with the lead nitrate on the surface of the grids, the newly applied lead nitrate material on the surface of the lead grid disassociates into lead Pb²⁺ ions and (NO₃)¹⁻ ions. The nitrate polyatomic ions which are released into solution when the lead nitrate is dissolved on contact with the alkaline paste, or more specifically the water component of the paste, become a spectator ion as the lead ions are made available for the formation of lead sulfate at the grid to paste interface. Although lead sulfate has a very low electrical conductivity compared to the lead or lead alloy grid material and that of the active material produced after formation, lead dioxide on the positive grid and sponge lead on the negative grid, it is the precursor material for the electrolytic formation of the active material and thus its position and uniform distribution across the entire faced of the grid to active material interface promotes the establishment of a uniform layer of electrically conductive and stable materials at this critical juncture point of the assembly.

Likewise, when the lead nitrate comes into contact with the sulfuric acid component of the paste liquid portion, it allows for the establishment of uniformly distributed formation of the sulfate of tetravalent lead, lead disulfate, Pb(SO₄)₂. This molecule thus reacts with water to form lead dioxide and sulfuric acid as follows:

2PbNO₃+2H₂SO₄=Pb(SO₄)₂+NO₃+H

Pb(SO₄)₂+2H₂O=PbO₂+2H₂SO₄

The reaction between the lead oxide paste and lead ions allows for the development of lead sulfate and lead dioxide material that completely covers the surface of the grid at the interface between the grid and the applied paste.

During the formation process and as the charging current is applied to the unformed battery assembly, chemical reactions are initiated at the interface of the lead grid and the paste surface whereby lead sulfate is chemically converted to lead dioxide on the positive grid and lead sulfate is converted to sponge lead on the negative plate as shown by the following reversible equation:

PbO₂+Pb+H₂SO₄><2PbSO₄+2H₂O

The formation process initiates at the surface of the grid and out through the paste mass as the formation process progresses. By providing the well defined lead sulfate and lead dioxide material at this critical junction point of the assembly, the formation process is no longer required to overcome the high resistance of the previous lead oxide layer on the grid surface and now has infinitely more current paths by which to initiate the chemical conversion of lead sulfate to lead dioxide on the positive and sponge lead on the negative. This along with the previously mentioned surface roughness that is developed by the chemical etching of the grid in the plasma treatment system provides a very high surface area.

The addition of the OAGDP process to the conventional lead acid manufacturing method provides a significantly larger surface area to which the active material can adhere to not by mechanical means only as previous assemblies. The surface grip thus developed is significantly more uniform and devoid of fractures and vacancies that have plagued the industry with poor active material adhesion and the subsequent reduction in the delivery of the potential energy contained in the active mass for usable work.

Further, the development of the chemical bridge across the entire surface greatly improves the electrical conductivity between the grid and the active material thus allowing for significant reduction if the energy required for the initial formation of the battery and the reluctance to accept recharge in the battery during use. The dramatic increase in surface grip and the uniformly distributed chemical bridge that is established enables the use of thinner grids and stamped grids which heretofore have been limited in their applicability due to the poor mechanical adhesion of the active mass to the lead grid support structure.

The reduction in active material shedding that is the primary cause of battery failure is dramatically reduced and the ability to utilize the theoretical amount of chemical energy based on the amount of active material in the cell is increased from the present 25% to 35% to a much higher efficiency. This fact alone lends the use of the new process and the lead acid battery for implementation in electric vehicles which thus far has been seen in limited use or only in recreational vehicles.

In addition to the use of OAGDP to form a uniform lead nitrate crystalline surface on the lead and lead alloy grids, OAGDP can also be used to convert red lead (Pb₃O₄) to beta lead dioxide by selecting a feed stock having a composition which allows such a reaction when the composition of the feed stock is broken down in reactive species during the OAGDP system. To use OAGDP to generate lead dioxide from red lead, red lead powder is mixed with water and other liquids to form a slurry. The slurry is then applied to the surface of the grids, which have been previously exposed to OAGDP so that there is a lead nitrate surface on the grids. The red lead slurry reacts with the lead nitrate and releases lead ions, among other constituents, that provides for mechanical adhesion of the slurry to the grids. The red lead grids are then placed back in the chamber and exposed to the OAGDP atmosphere to convert the red lead to lead dioxide.

The foregoing description of the present invention has been presented to illustrate the principles of the invention and not to limit the invention to the particular embodiments illustrated. It is intended that the scope of the invention be defined by all of the embodiments encompassed within the following claims and their equivalents.

I claim:

1. A process for treating a metallic surface comprising:
placing a metallic surface in a chamber having two electrodes therein;
passing a feed stream into the chamber between the two electrodes;
using the electrodes to apply a one atmosphere glow discharge plasma (OAGDP) system to form reactive atomic and molecular species of the feed stream thereby creating a reactive atmosphere in the chamber;
exposing the metallic surface to the reactive atmosphere so that at least one resultant reaction occurs between the reactive atomic and molecular species and the metallic surface to treat the metallic surface; and
removing the treated metallic surface from the chamber.

2. The process for treating a metallic surface of claim 1, further comprising:
providing a metallic surface having at least one lead component;
providing a feed stream containing oxygen and nitrogen; and
using the electrodes to apply a OAGDP system form reactive atomic and molecular species of the oxygen and nitrogen of the feed stream.

3. The process for treating a metallic surface of claim 2, further comprising:
reacting the reactive atomic and molecular species of the oxygen and nitrogen of the feed stream with the at least one lead component of the metallic surface to create a lead nitrate layer on the metallic surface.

4. The process for treating a metallic surface of claim 3, further comprising:
reacting the reactive atomic and molecular species of the oxygen and nitrogen of the feed stream with the metallic surface to chemically etch and clean the metallic surface.

5. The process for treating a metallic surface of claim 4, further comprising:
exposing the lead nitrate layer on the metallic surface to lead sulfate and water to create a lead dioxide layer on the metallic surface.

6. The process for treating a metallic surface of claim 5, further comprising:
providing a feed stream containing oxygen, nitrogen, and water; and
controlling a relative humidity in the chamber by atomization of the water during the OADGP system.

7. The process for treating a metallic surface of claim 6, further comprising:
providing a feed stream containing oxygen, nitrogen, water, and carbon dioxide.

8. The process for treating a metallic surface of claim 6, further comprising:
using a catalyst during the OAGDP system to expedite the resultant reaction between the reactive atomic and molecular species and the metallic surface.

9. The process for treating a metallic surface of claim 1, further comprising:
adjusting the composition of the feed stream to control the resultant reaction between the reactive atomic and molecular species and the metallic surface.

10. The process for treating a metallic surface of claim 9, further comprising:
adjusting a relative humidity inside the chamber, temperature inside the chamber, the composition of the feed stream to control the reactive atomic and molecular species and the metallic surface.

11. The process for treating a metallic surface of claim 3, further comprising:
mixing red lead powder with water to form a slurry;
applying the slurry to the lead nitrate layer on the metallic surface;
placing the metallic plates into the chamber again;
passing a feed stream into the chamber between the two electrodes;
using the electrodes to apply a OAGDP system to form reactive atomic and molecular species of the feed stream thereby creating a reactive atmosphere;
exposing the metallic surface to the reactive atmosphere so that a resultant reaction occurs between the reactive atomic and molecular species and the red lead to form lead dioxide; and
removing the metallic plates from the chamber.

12. A process for manufacturing lead acid batteries, comprising:
forming lead or lead alloy grids;
placing the grids in a chamber having two electrodes therein;
passing a feed stream into the chamber between the two electrodes;
using the electrodes to apply a one atmosphere glow discharge plasma (OAGDP) system to form reactive atomic and molecular species of the feed stream thereby creating a reactive atmosphere in the chamber;
exposing the grids to the reactive atmosphere so that at least one resultant reaction occurs between the reactive atomic and molecular species and the lead or lead alloy grids so that a layer of lead nitrate is formed on the grids;
removing the grids from the chamber;
forming lead oxide powder by milling lead in the presence of oxygen;
forming a paste by mixing the lead oxide with water and sulfuric acid;
applying the paste to grids so that the water and sulfuric acid of the paste reacts with the lead nitrate of the grids to form lead dioxide on the grids;
curing the grids; and
placing the grids into a battery case.

13. The process for manufacturing lead acid batteries of claim 12, further comprising:
providing a feed stream containing oxygen and nitrogen; and
using the electrodes to apply a OAGDP system form reactive atomic and molecular species of the oxygen and nitrogen of the feed stream.

14. The process for manufacturing lead acid batteries of claim 13, further comprising:
reacting the reactive atomic and molecular species of the oxygen and nitrogen of the feed stream with the lead and lead alloy grids to chemically etch and clean the grids.

15. The process for manufacturing lead acid batteries of claim 14, further comprising:
providing a feed stream containing oxygen, nitrogen, and water; and
controlling a relative humidity in the chamber by atomization of the water during the OADGP system.

16. The process for manufacturing lead acid batteries of claim 15, further comprising:
providing a feed stream containing oxygen, nitrogen, water, and carbon dioxide.

17. The process for manufacturing lead acid batteries of claim 16, further comprising:
using a catalyst during the OAGDP system to expedite the resultant reaction between the reactive atomic and molecular species and the lead and lead alloy grids.

18. The process for manufacturing lead acid batteries of claim 12, further comprising:
adjusting the composition of the feed stream to control the resultant reaction between the reactive atomic and molecular species and the metallic surface.

19. The process for manufacturing lead acid batteries of claim 18, further comprising:
adjusting a relative humidity inside the chamber, temperature inside the chamber, the composition of the feed stream to control the reactive atomic and molecular species and the metallic surface.

20. The process for manufacturing lead acid batteries of claim 13, further comprising:
mixing red lead powder with water to form a slurry;
applying the slurry to the lead nitrate layer on the lead and lead alloy grids;
placing the grids into the chamber again;
passing a feed stream into the chamber between the two electrodes;
using the electrodes to apply a OAGDP system to form reactive atomic and molecular species of the feed stream thereby creating a reactive atmosphere;
exposing the grids to the reactive atmosphere so that a resultant reaction occurs between the reactive atomic and molecular species and the red lead to form lead dioxide; and
removing the metallic plates from the chamber.

21. A process for manufacturing lead acid batteries, comprising:
forming lead or lead alloy grids;
forming lead oxide powder by milling lead in the presence of oxygen;
forming a paste by mixing the lead oxide with water and sulfuric acid;
applying the paste to grids;
placing the pasted grids in a chamber having two electrodes therein;
passing a feed stream into the chamber between the two electrodes;
using the electrodes to apply a one atmosphere glow discharge plasma (OAGDP) system to form reactive atomic and molecular species of the feed stream thereby creating a reactive atmosphere in the chamber;
exposing the grids to the reactive atmosphere so that at least one resultant reaction occurs between the reactive atomic and molecular species and the lead or lead alloy grids so that a layer of lead nitrate is formed on the grids;
allowing the lead nitrate to react with the water and sulfuric acid of the paste to form lead dioxide on the grids;
removing the grids from the chamber;
curing the grids; and
placing the grids into a battery case.
